(19) United States
(12) Patent Application Publication
(10) Pub. No.: US 2025/0040272 A1
(43) Pub. Date: Jan. 30, 2025

(54) IMAGE SENSOR

(71) Applicant: SAMSUNG ELECTRONICS CO., LTD., Suwon-si (KR)

(72) Inventors: Junoh KIM, Suwon-si (KR); Munhwan Kim, Suwon-si (KR); Jieun Lee, Suwon-si (KR)

(73) Assignee: SAMSUNG ELECTRONICS CO., LTD., Suwon-si (KR)

(21) Appl. No.: 18/756,899

(22) Filed: Jun. 27, 2024

(30) Foreign Application Priority Data
Jul. 24, 2023 (KR) 10-2023-0096131

(51) Int. Cl. H01L 27/146

(52) U.S. Cl. CPC H01L 27/14607; H01L 27/14621; H01L 27/14627; H01L 27/1463

(57) ABSTRACT

There is provided an image sensor including a substrate, a plurality of pixel groups respectively including a plurality of photodiodes provided in the substrate, a pixel isolation pattern provided between the plurality of photodiodes in the substrate, an auxiliary isolation pattern provided to extend inside from a surface of the substrate, and a micro lens provided on the surface of the substrate. The pixel isolation pattern includes an outer isolation pattern provided between the plurality of pixel groups and an inner isolation pattern provided between the plurality of photodiodes within the plurality of pixel group, and the auxiliary isolation pattern is provided between the outer isolation pattern and the inner isolation pattern that are spaced apart from each other or between a plurality of inner isolation patterns that are spaced apart from each other.

### CROSS-REFERENCE TO RELATED APPLICATION

This application is based on and claims priority to Korean Patent Application No. 10-2023-0096131 filed in the Korean Intellectual Property Office on Jul. 24, 2023, the entire contents of which are incorporated herein by reference.

### BACKGROUND

### 1. Field

The disclosure relates to an image sensor.

### 2. Description of the Related Art

A CMOS image sensor is a solid-state imaging device using a complementary metal-oxide semiconductor (CMOS). Compared to CCD image sensors with high-voltage analog circuit, CMOS image sensors have advantages of low manufacturing cost and low power consumption due to a small size of the device. As such, CMOS image sensors are installed in home appliances in addition to portable devices such as smartphones and digital cameras.

A pixel array provided in the CMOS image sensor includes a photoelectric conversion element such as a photodiode for each pixel. The photodiode may generate an electrical signal that varies according to an amount of incident light, and the CMOS image sensor may synthesize an image by processing the electrical signal.

Recently, according to demands for high-resolution images, a pixel provided in the CMOS image sensor is required to be further down-sized. As the demand for down-sizing increases, incident light may not be properly sensed by the CMOS image sensor, or noise may occur due to interference between elements having increased integration.

However, despite the down-sizing of the CMOS image sensor, demands for image quality improvement and additional functions are increasing.

### SUMMARY

Embodiments are to provide an image sensor having more improved optical characteristics.

According to an aspect of the disclosure, there is provided an image sensor including: a substrate including a first surface and a second surface; a plurality of pixel groups, each of the plurality of pixel groups including a plurality of photodiodes provided in the substrate; a pixel isolation pattern provided between the plurality of photodiodes in the substrate; an auxiliary isolation pattern provided in the substrate, the auxiliary isolation pattern extending from the second surface of the substrate into the substrate; and a micro lens provided on the second surface of the substrate, wherein the pixel isolation pattern includes: an outer isolation pattern provided between the plurality of pixel groups, and an inner isolation pattern including: a first inner isolation pattern provided between two first adjacent photodiodes, among the plurality of photodiodes, and a second inner isolation pattern provided between two second adjacent photodiodes, among the plurality of photodiodes, and wherein the auxiliary isolation pattern is provided between the outer isolation pattern and one of the first and the second inner isolation patterns that are spaced apart from each other or between the first inner isolation pattern and the second inner isolation pattern that are spaced apart from each other.

According to an aspect of the disclosure, there is provided an image sensor including: a substrate including a first surface and a second surface; a plurality of pixel groups, each of the plurality of pixel groups including a plurality of photodiodes provided in the substrate; a pixel isolation pattern provided between the plurality of photodiodes in the substrate; an element isolation pattern provided in the substrate, the element isolation pattern extending inside the substrate from the first surface of the substrate; and an auxiliary isolation pattern provided in the substrate, the auxiliary isolation pattern extending inside the substrate from the second surface of the substrate, wherein the pixel isolation pattern includes: an outer isolation pattern provided between the plurality of pixel groups, and an inner isolation pattern including: a first inner isolation pattern provided between two first adjacent photodiodes, among the plurality of photodiodes, and a second inner isolation pattern provided between two second adjacent photodiodes, among the plurality of photodiodes, and wherein the auxiliary isolation pattern is provided between the outer isolation pattern and one of the first and the second inner isolation patterns that are spaced apart from each other or between the first inner isolation pattern and the second inner isolation pattern that are spaced apart from each other.

According to an aspect of the disclosure, there is provided an image sensor including: a substrate comprising a first surface and a second surface; a plurality of pixel groups, each of the plurality of pixel groups comprising a plurality of photodiodes provided in the substrate; a plurality of pixel isolation patterns, each provided between adjacent photodiodes among the plurality of photodiodes in the substrate; and an auxiliary isolation pattern provided in the substrate, the auxiliary isolation pattern extending inside the substrate from the first surface of the substrate and provided between two pixel isolation patterns, among the plurality of pixel isolation patterns spaced apart from each other, wherein each of the plurality of pixel isolation patterns includes: an isolation conductive pattern extending inwardly from the second surface of the substrate, a capping insulation pattern extending inwardly from the first surface of the substrate, and an isolation insulation pattern provided on side surfaces of the isolation conductive pattern and the capping insulation pattern.

The image sensor according to the embodiments may include an auxiliary isolation pattern, thereby improving optical characteristics of the image sensor.

### BRIEF DESCRIPTION OF DRAWINGS

FIG. 1 illustrates a schematic block diagram of an image sensor according to an embodiment.

FIG. 2 illustrates a top plan view of a pixel array of an image sensor according to an embodiment.

FIG. 3 illustrates a circuit diagram of a pixel of an image sensor according to an embodiment.

FIGS. 4 and 5 illustrate schematic top plan views of a pixel group of an image sensor according to an embodiment.

FIG. 6 illustrates a cross-sectional view taken along line A-A′ of FIG. 4.

FIG. 7 illustrates a cross-sectional view taken along line B-B′ of FIG. 4.

FIGS. 8 to 14 illustrate schematic top plan views of pixel groups of image sensors according to some embodiments.

FIGS. 15 and 16 illustrate schematic top plan views of a color filter of an image sensor according to an embodiment.

FIGS. 17 and 18 illustrate schematic top plan views of a micro lens of an image sensor according to an embodiment.

FIGS. 19 to 22 are drawings illustrating various examples of electronic devices to which image sensors according to example embodiments are applied.

### DETAILED DESCRIPTION

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

In order to clearly describe the disclosure, parts or portions that are irrelevant to the description are omitted, and identical or similar constituent elements throughout the specification are denoted by the same reference numerals.

In the drawings, the size and thickness of each element are arbitrarily illustrated for ease of description, and the disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means provided on or below the object portion, and does not necessarily mean provided on the upper side of the object portion based on a gravitational direction.

Throughout the specification, when a component is described as being “connected to,” or “coupled to” another component, it may be directly “connected to,” or “coupled to” the other component, or there may be one or more other components intervening therebetween. In contrast, when an element is described as being “directly connected to,” or “directly coupled to” another element, there can be no other elements intervening therebetween. Likewise, similar expressions, for example, “between” and “immediately between,” and “adjacent to” and “immediately adjacent to,” are also to be construed in the same way. As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof. As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment (e.g., as to what an example or embodiment may include or implement) means that at least one example or embodiment exists where such a feature is included or implemented, while all example embodiments are not limited thereto.

The embodiments of the disclosure are example embodiments, and thus, the disclosure is not limited thereto and may be realized in various other forms. As is traditional in the field, embodiments may be described and illustrated in terms of blocks, as shown in the drawings, which carry out a described function or functions. These blocks, which may be referred to herein as units or modules or the like, or by names such as device, logic, circuit, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

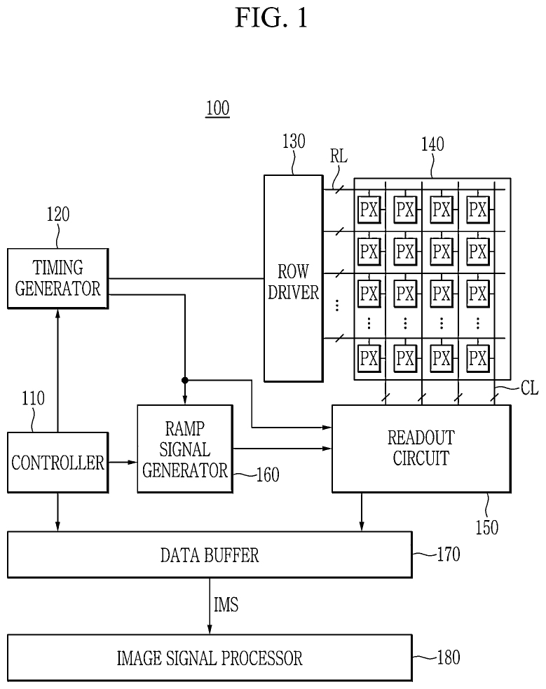

An image sensor according to an embodiment will be described with reference to FIG. 1.

FIG. 1 illustrates a schematic block diagram of an image sensor according to an embodiment.

Referring to FIG. 1, according to an embodiment, an image sensor 100 may include a pixel array 140 and a logic circuit for controlling the pixel array 140. However, the disclosure is not limited thereto, and as such, the image sensor 100 may include other components.

The logic circuit may include, for example, a controller 110, a timing generator 120, a row driver 130, a readout circuit 150, a ramp signal generator 160, and a data buffer 170. However, the disclosure is not limited thereto, and as such, the logic circuit may include other components.

In addition, the image sensor 100 may further include an image signal processor 180. For example, the image signal processor 180 may be provided in the images sensor 100. However, the disclosure is not limited thereto, and as such, according to another embodiment, the image signal processor 180 may be provided outside the image sensor 100. The image sensor 100 may generate an image signal by converting light received from the outside into an electrical signal. The image signal may be provided to the image signal processor 180.

The image sensor 100 may be mounted on an electronic device having an imaging function or an optical sensing function. For example, the image sensor 100 may be mounted on electronic devices, such as a camera, a smartphone, a wearable device, an Internet of things (IoT) device, a home appliance, a tablet personal computer (PC), a navigation device, a drone, an advanced driver assistance systems (ADAS), and the like. In addition, the image sensor 100 may be mounted on an electronic device provided as a component in a vehicle, furniture, a manufacturing facility, a door, various measurement devices, or the like.

The pixel array 140 may include a plurality of pixels PX, and a plurality of row lines RL and a plurality of column lines CL respectively connected to the plurality of pixels PX.

According to an embodiment, each pixel PX may include at least one photodiode. The photodiode may sense incident light, and may convert the incident light into an electrical signal according to an amount of the light. For example, the electrical signal may be an analog pixel signal, and as such, the pixel array may output a plurality of analog pixel signals.

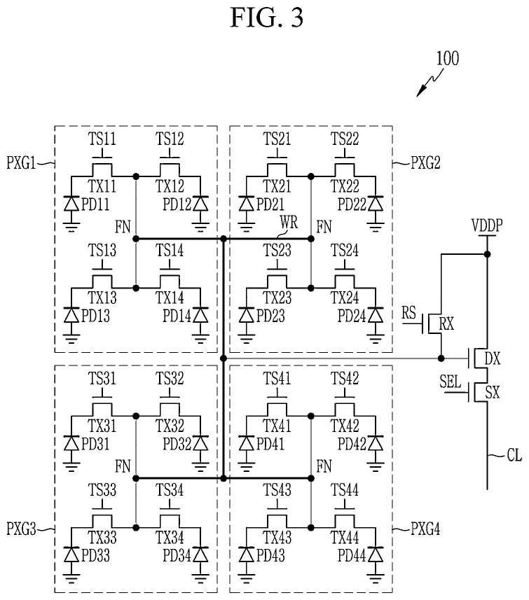

The photodiode may be a photodiode PD as shown in FIG. 3, a pinned diode, or the like. In addition, the photodiode may be a single-photon avalanche diode (SPAD) applied to a 3D sensor pixel.

The level of the analog pixel signal output from the photodiode may be proportional to an amount of charge output from the photodiode. That is, the level of the analog pixel signal output from the photodiode may be determined according to an amount of light received into the pixel array 140.

The plurality of row lines RL may be connected to the plurality of pixels PX. For example, a control signal output from the row driver 130 to the row line RL may be transmitted to a gate of a transistor of the plurality of pixels PX connected to the corresponding row line RL. The column line CL may be provided to cross the row line RL, and may be connected to the plurality of pixels PX. The plurality of pixel signals output from the plurality of pixels PX may be transmitted to the readout circuit 150 through the plurality of column lines CL.

According to an embodiment, the plurality of pixels PX may be provided along a plurality of columns and a plurality of rows, and one analog pixel signal may be output for each pixel PX. However, the embodiment is not limited thereto, and numerous variations are possible. For example, the plurality of pixels PX may be grouped in the form of a plurality of columns and a plurality of rows to configure one unit pixel. One unit pixel may include a plurality of pixels PX arranged in the form of two columns and two rows, and one unit pixel may output one analog pixel signal.

The controller 110 may control one or more operations of the image sensor 100. For example, the controller 110 may control the operation timing of each of the timing generator 120, the row driver 130, the readout circuit 150, the ramp signal generator 160, and the data buffer 170. For example, the controller 110 may output one or more control signals to control one or more of constituent elements 120, 130, 150, 160, and 170 described above.

According to an embodiment, the controller 110 may receive a mode signal indicating an imaging mode from an application processor, and may control an overall operation of the image sensor 100 based on the received mode signal. For example, the application processor may determine the imaging mode of the image sensor 100 according to various scenarios or conditions, and may provide the determined result to the controller 110 as a mode signal. The various scenarios may include, but is not limited to, illumination of the imaging environment, a user resolution setting, a sensed or learned state.

The controller 110 may control the plurality of pixels PX of the pixel array 140 to output pixel signals according to the imaging mode. For example, based on the imaging mode, the pixel array 140 may output a pixel signal for each of the plurality of pixels PX or a pixel signal for some of the plurality of pixels PX, and the readout circuit 150 may sample and process pixel signals transmitted from the pixel array 140.

The timing generator 120 may generate a signal serving as a reference for operation timing of components of the image sensor 100. The timing generator 120 may control the timing of the row driver 130, the readout circuit 150, and the ramp signal generator 160. The timing generator 120 may provide a control signal for controlling the timing of the row driver 130, the readout circuit 150, and the ramp signal generator 160.

The row driver 130 may generate a control signal for driving the pixel array 140 based on the control signal of the timing generator 120, and may provide control signals to the plurality of pixels PX of the pixel array 140 through the plurality of row lines RL.

According to an embodiment, the row driver 130 may control the pixel PX to sense incident light in a row line unit. The row line unit may include at least one row line RL. For example, the row driver 130 may generate a transmission signal for controlling a transmission transistor, a reset control signal for controlling a reset transistor, and a selection control signal for controlling a selection transistor to provide the generated signals to the pixel array 140.

The readout circuit 150 may convert the pixel signal (or electrical signal) from the pixel PX connected to the row line RL selected from the plurality of pixels PX based on the control signal from the timing generator 120 into a pixel value representing the amount of light.

The readout circuit 150 may convert a pixel signal output through the corresponding column line CL into a pixel value. For example, the readout circuit 150 may convert a pixel signal into a pixel value by comparing a ramp signal and a pixel signal. The pixel value may be image data having a plurality of bits. Specifically, the readout circuit 150 may include a selector, a plurality of comparator, and a plurality of counter circuits.

The ramp signal generator 160 may generate a reference signal to transmit it to the readout circuit 150. The ramp signal generator 160 may include a current source, a resistor, and a capacitor. The ramp signal generator 160 adjusts a ramp voltage, which is a voltage applied to a ramp resistor, by adjusting a current amount of a variable current source or a resistance value of a variable resistor, so that the ramp signal generator 160 may generate a plurality of ramp signals that fall or rise with a slope determined according to the current amount of the variable current source or the resistance value of the variable resistor.

The data buffer 170 may store pixel values of the plurality of pixels PX connected to the selected column line CL transmitted from the readout circuit 150, and may output the stored pixel values based on an enable signal from the controller 110.

The image signal processor 180 may perform image signal processing on the image signal received from the data buffer 170. For example, the image signal processor 180 may receive a plurality of image signals from the data buffer 170, and may synthesize the received image signals to generate one image.

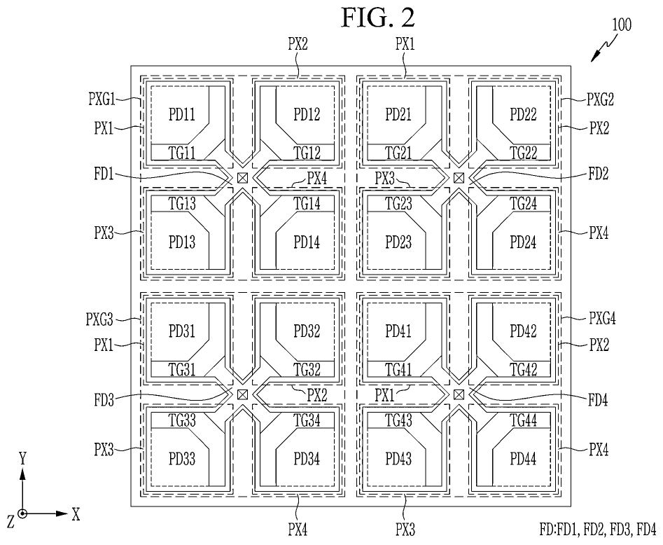

Hereinafter, pixels of an image sensor according to an embodiment will be described with reference to FIG. 2.

FIG. 2 illustrates a top plan view of a pixel array of an image sensor according to an embodiment.

Referring to FIG. 2, the image sensor 100 according to the embodiment may include a plurality of pixel groups, for example, a first pixel group PXG1, a second pixel group PXG2, a third pixel group PXG3 and a fourth pixel group PXG4. The plurality of pixel groups may be arranged in a plurality of rows and columns. In FIG. 2, the first to fourth pixel groups PXG1 to PXG4 arranged in two rows and two columns are shown, but this is for convenience of description, and as such, according to another embodiment, the pixel array 140 may include a larger number of pixel groups. For example, the number of the plurality of pixel groups may be determined according to the resolution of the pixel array 140 of the image sensor 100.

The plurality of row lines (RL in FIG. 1) extend in a first direction (X direction), and pixel groups provided in the same row may be connected to a same row line. The plurality of column lines (CL in FIG. 1) extend in a second direction (Y-axis direction), for example, and pixels provided to the same column may be connected to a same column line. A pixel signal may be read through a column line in a row unit from a plurality of pixels.

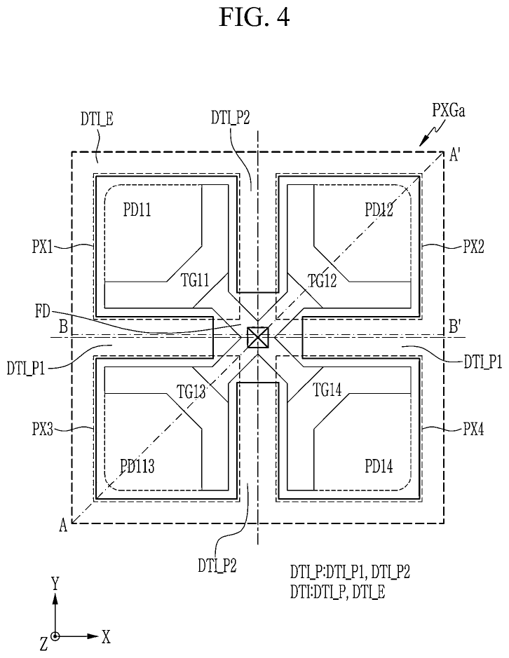

Each of the first to fourth pixel groups PXG1 to PXG4 may include a first pixel PX1, a second pixel PX2, a third pixel PX3 and a first pixel PX4 arranged along a plurality of columns and a plurality of rows. Each of the first to fourth pixel groups PXG1 to PXG4 may include a plurality of floating diffusion areas FD in which charges are stored. For example, the first pixel group PXG1 may include a first floating diffusion area FD1, the second pixel group PXG2 may include a second floating diffusion area FD2, the third pixel group PXG3 may include a third floating diffusion area FD3 and the fourth pixel group PXG4 may include a fourth floating diffusion area FD4. The plurality of floating diffusion areas FD may be electrically connected through a connection wire within a pixel. The first to fourth pixel groups PXG1 to PXG4 may have substantially the same pixel structure, and the pixel structure will be described in detail below in FIG. 4.

Hereinafter, a pixel circuit structure of an image sensor according to an embodiment will be described with reference to FIG. 3.

FIG. 3 illustrates a pixel circuit diagram of an image sensor according to an embodiment.

Referring to FIG. 3, the image sensor according to the embodiment may include first to fourth pixel groups PXG1 to PXG4, a reset transistor RX, a driving transistor DX, and a selection transistor SX. The reset transistor RX, the driving transistor DX, and the selection transistor SX may configure an output circuit of the first to fourth pixel groups PXG1 to PXG4. For example, the output circuit of the image sensor 100 may include the reset transistor RX, the driving transistor DX, and the selection transistor SX.

The first pixel group PXG1 may include a plurality of photodiodes and a plurality of transmission transistors. For example, the plurality of photodiodes may include a first photodiode PD11, a second photodiode PD12, a third photodiode PD13 and a fourth photodiode PD14, and the plurality of transmission transistors may include a first transmission transistor TX11, a second transmission transistor TX12, a third transmission transistor TX13 and a fourth transmission transistor TX14. The first to fourth photodiodes PD11 to PD14 may respectively generate photocharges (hereinafter, referred to as charges) corresponding to an amount of received light.

The first to fourth photodiodes PD11 to PD14 may be connected to the first to fourth transmission transistors TX11 to TX14, respectively. The first to fourth transmission transistors TX11 to TX14 of the first pixel group PXG1 may be turned on based on an active level (for example, logic high) of transmission signals TS11 to TS14, respectively.

The second pixel group PXG2 may include a plurality of photodiodes and a plurality of transmission transistors. For example, the plurality of photodiodes may include a first photodiode PD21, a second photodiode PD22, a third photodiode PD23 and a fourth photodiode PD24, and the plurality of transmission transistors may include a first transmission transistor TX21, a second transmission transistor TX22, a third transmission transistor TX23 and a fourth transmission transistor TX24. The first to fourth photodiodes PD21 to PD24 and the first to fourth transmission transistors TX21 to TX24 may be respectively connected to the first to fourth photodiodes PD21 to PD24. The first to fourth transmission transistors TX21 to TX24 of the second pixel group PXG2 may be turned on based on an active level (for example, logic high) of transmission signals TS21 to TS24, respectively.

The third pixel group PXG3 may include a plurality of photodiodes and a plurality of transmission transistors. For example, the plurality of photodiodes may include a first photodiode PD31, a second photodiode PD32, a third photodiode PD33 and a fourth photodiode PD34, and the plurality of transmission transistors may include a first transmission transistor TX31, a second transmission transistor TX32, a third transmission transistor TX33 and a fourth transmission transistor TX34. The first to fourth photodiodes PD31 to PD34 and first to fourth transmission transistors TX31 to TX34 may be respectively connected to the first to fourth photodiodes PD31 to PD34. The first to fourth transmission transistors TX31 to TX34 of the third pixel group PXG3 may be turned on based on an active level (for example, logic high) of transmission signals TS31 to TS34, respectively.

The fourth pixel group PXG4 may include a plurality of photodiodes and a plurality of transmission transistors. For example, the plurality of photodiodes may include a first photodiode PD41, a second photodiode PD42, a third photodiode PD43 and a fourth photodiode PD44, and the plurality of transmission transistors may include a first transmission transistor TX41, a second transmission transistor TX42, a third transmission transistor TX43 and a fourth transmission transistor TX44. The first to fourth photodiodes PD41 to PD44 and first to fourth transmission transistors TX41 to TX44 may be respectively connected to the first to fourth photodiodes PD41 to PD44. The first to fourth transmission transistors TX41 to TX44 of the fourth pixel group PXG4 may be turned on based on an active level (for example, logic high) of transmission signals TS41 to TS44, respectively.

The plurality of transmission signals TS11, TS12, TS13, TS14, TS21, TS22, TS23, TS24, TS31, TS32, TS33, TS34, TS41, TS42, TS43, and TS44 may have active levels at the same time point or different time points according to a read mode. For example, in a first read mode, the plurality of transmission signals TS11 to TS14, TS21 to TS24, TS31 to TS34, and TS41 to TS44 are different signals, and may have active levels at different time points. In a second read mode (for example, charge summation mode), the plurality of transmission signals TS11 to TS14, TS21 to TS24, TS31 to TS3, and TS41 to TS44 are the same signal, and may have active levels at the same time point. In a third read mode, the transmission signals TS11 to TS14 of the first pixel group PXG1 may be the same signal, the transmission signals TS21 to TS24 of the second pixel group PXG2 may be the same, the transmission signals TS31 to TS34 of the third pixel group PXG3 may be the same signal, and the transmission signals TS41 to TS44 of the fourth pixel group PXG4 may be the same signal, but are not limited thereto.

The first to fourth transmission transistors TX11 to TX14, TX21 to TX24, TX31 to TX34, and TX41 to TX44 respectively provided in the first to fourth pixel groups PXG1 to PXG4 may be turned on to transmit charges generated from the corresponding photodiodes to the floating diffusion node FN. The first to fourth pixel groups PXG1 to PXG4 may include first to fourth floating diffusion areas FD1 to FD4 shown in FIG. 2, respectively. Since the first to fourth floating diffusion areas are electrically connected to each other through a connection wire, a single floating diffusion node FN may be formed in each of the first to fourth pixel groups PXG1 to PXG4.

Accordingly, capacitance of a capacitor formed at the floating diffusion node FN may be greater than that of each of the first to fourth floating diffusion areas FD1 to FD4 shown in FIG. 2. For example, the capacitance of the capacitor formed at the floating diffusion node FN may be 4 times the capacitance of each of the first to fourth floating diffusion areas FD1 to FD4 shown in FIG. 2. However, the disclosure is not limited thereto, and such, capacitance of the capacitor formed at the floating diffusion node FN may have a different value.

A reset signal RS may be applied to a gate of the reset transistor RX, a power voltage VDDP may be supplied to one end of the reset transistor RX, and the other end of the reset transistor RX may be connected to the floating diffusion node FN. The reset transistor RX is turned on based on the active level of the reset signal RS, so that the floating diffusion node FN may be reset to the power voltage VDDP.

The driving transistor DX may output a pixel signal according to the voltage of the floating diffusion node FN. A gate of the driving transistor DX is connected to the floating diffusion node FN, the power voltage VDDP is supplied to one end of the driving transistor DX, and the other end of the driving transistor DX is connected to one end of the selection transistor SX. The driving transistor DX may configure a source follower circuit, and may output a voltage at a level corresponding to the charges accumulated in the floating diffusion node FN as a pixel signal.

In an example case in which the selection transistor SX is turned on by a selection signal SEL, a pixel signal from the driving transistor DX may be transmitted to the readout circuit 150 through the column line CL. The selection signal SEL is applied to the gate of the selection transistor SX, and the other end of the selection transistor SX is connected to the column line CL.

Meanwhile, in FIG. 3, the first to fourth pixel groups PXG1 to PXG4 are shown to include one reset transistor RX, one driving transistor DX, and one selection transistor SX, but are not limited thereto. For example, the first to fourth pixel groups PXG1 to PXG4 may include two reset transistors, two driving transistors, and two selection transistors. According to another embodiment, the first to fourth pixel groups PXG1 to PXG4 may include three or more reset transistors, driving transistors, and selection transistors.

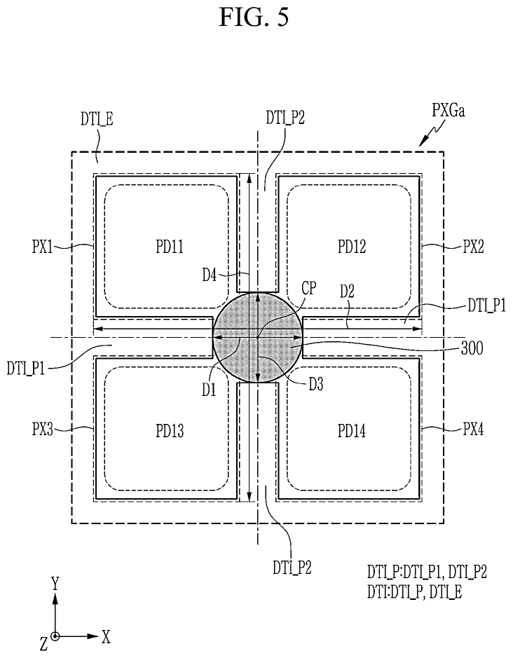

Hereinafter, one pixel group of an image sensor according to an embodiment will be described with reference to FIGS. 4 and 5.

FIGS. 4 and 5 illustrate schematic top plan views of a pixel group of an image sensor according to an embodiment.

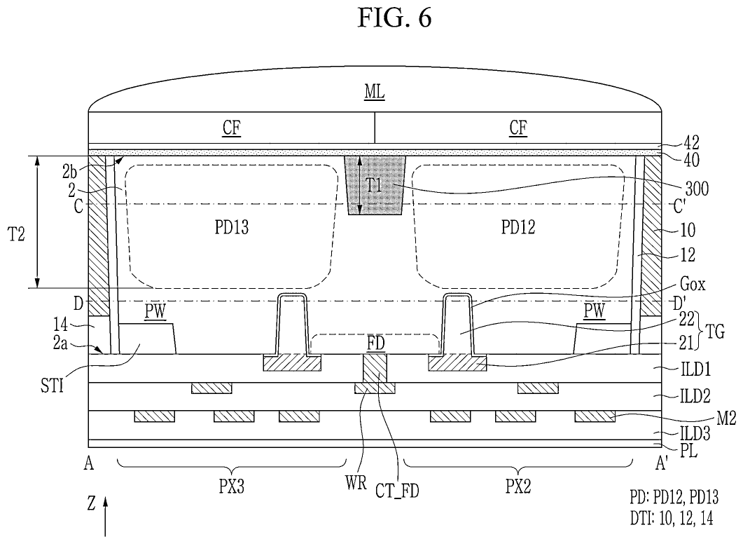

FIG. 4 illustrates a top plan view taken along line D-D′ of FIG. 6, and FIG. 5 illustrates a top plan view taken along line C-C′ of FIG. 6.

Accordingly, FIG. 4 illustrates a pixel isolation pattern DTI, first to fourth photodiodes PD11 to PD14, transmission gates (e.g., TG11, TG12, TG13 and TG14), and a floating diffusion area FD, and FIG. 5 illustrates the pixel isolation pattern DTI, the first to fourth photodiodes PD11 to PD14, and an auxiliary isolation pattern 300.

A pixel group PXGa of FIGS. 4 and 5 may correspond to each of the first to fourth pixel groups PXG1 to PXG4 of FIG. 2. Hereinafter, for convenience of description, one pixel group PXGa will be described.

The pixel group PXGa may include the first to fourth pixels PX1 to PX4 and the pixel isolation pattern DTI arranged along a plurality of columns and a plurality of rows. The pixel group PXGa may include the first to fourth photodiodes PD11 to PD14, the first to fourth transmission gates TG11 to TG14, and the floating diffusion area FD.

Each of the first to fourth pixels PX1 to PX4 of the pixel group PXGa may include one photodiode and one transmission gate. For example, the first pixel PX1 may include the first photodiode PD11 and the first transmission gate TG11. The second pixel PX2 may include the second photodiode PD12 and the second transmission gate TG12. The third pixel PX3 may include the third photodiode PD13 and the third transmission gate TG13. The fourth pixel PX4 may include the fourth photodiode PD14 and the fourth transmission gate TG14. The first to fourth photodiodes PD11 to PD14 may be provided along the first direction (X direction) and the second direction (Y direction) crossing the first direction (X direction).

The first to fourth transmission gates TG11 to TG14 may be respective gates of the first to fourth transmission transistors TX11 to TX14 shown in FIG. 3. The first to fourth transmission transistors TX11 to TX14 shown in FIG. 3 may be respectively connected to the first to fourth photodiodes PD11 to PD14. The floating diffusion area FD may be connected to each of the first to fourth pixels PX11 to PX14.

The pixel isolation pattern DTI may be provided between adjacent pixel groups PXGa and between adjacent pixels PX. The pixel isolation pattern DTI may isolate adjacent pixel groups PXG. In addition, the pixel isolation pattern DTI may isolate photodiodes PD included in each pixel PX. For example, the pixel isolation pattern DTI may electrically and/or optically isolate the first to fourth photodiodes PD11 to PD14 included in the pixel group PXGa. The pixel isolation pattern DTI may include an outer isolation pattern DTI_E for isolating each pixel group PXGa and an inner isolation pattern DTI_P for isolating the plurality of pixels PX included in each pixel group PXGa from each other. For example, the outer isolation pattern DTI_E may be configured to separate each pixel group PXGa and the inner isolation pattern DTI_P may be configured to separate the plurality of pixels PX included in each pixel group PXGa from each other. For example, the outer isolation pattern DTI_E may be provided as a barrier between adjacent pixel groups PXGa and the inner isolation pattern DTI_P may be provided as a barrier between adjacent pixels PX included in each pixel group PXGa.

The outer isolation pattern DTI_E may surround each pixel group PXGa. That is, the outer isolation pattern DTI_E may surround the first to fourth photodiodes PD11 to PD14.

The inner isolation pattern DTI_P may be provided between adjacent pixels PX. For example, the inner isolation pattern DTI_P may be provided between the first to fourth pixels PX1 to PX4, respectively. Each of the first to fourth pixels PX1 to PX4 may be isolated by the inner isolation pattern DTI_P. In addition, the inner isolation pattern DTI_P may extend in the first direction (X direction) and the second direction (Y direction) in a plan view, and may be provided between the photodiodes PD adjacent to each other. The inner isolation pattern DTI_P may electrically and/or optically isolate adjacent photodiodes from each other. The inner isolation patterns DTI_P may be spaced apart from each other at a central portion CP within each pixel group PXGa.

The inner isolation pattern DTI_P may include a first inner isolation pattern DTI_P1 and a second inner isolation pattern DTI_P2.

The first inner isolation pattern DTI_P1 may extend in the first direction (X direction). The first inner isolation pattern DTI_P1 may be connected to the outer isolation pattern DTI_E provided on both sides in the first direction (X direction). That is, the first inner isolation pattern DTI_P1 may be provided between inner walls of the outer isolation pattern DTI_E extending in the second direction (Y direction). The first inner isolation patterns DTI_P1 may be spaced apart from each other at the central portion CP of the pixel group PXGa. The first inner isolation pattern DTI_P1 may protrude in the first direction (X direction) toward the central portion CP of the pixel group PXGa. For example, each of two first inner isolation patterns DTI_P1 protruding in the first direction (X direction) may be spaced apart from the central portion CP of the pixel group PXGa. The first inner isolation pattern DTI_P1 may be symmetric with respect to the central portion CP of the pixel group PXGa. The central portion CP may include a center point of the pixel group PXGa.

For example, a first distance D1 at which the first inner isolation patterns DTI_P1 are spaced apart from each other in the first direction (X direction) may be 0.5 times or less of a second distance D2 between the inner walls of the outer isolation pattern DTI_E extending in the second direction (Y direction). For example, the first distance D1 at which the first inner isolation patterns DTI_P1 are spaced apart from each other in the first direction (X direction) may be 0.05 to 0.4 times the second distance D2 between the inner walls of the outer isolation pattern DTI_E extending in the second direction (Y direction). That is, a sum of lengths of the first inner isolation patterns DTI_P1 extending in the first direction (X direction) may be greater than the first distance D1 at which the first inner isolation patterns DTI_P1 are spaced apart from each other in the first direction (X direction).

The second inner isolation pattern DTI_P2 may extend in the second direction (Y direction) crossing the first direction (X direction). The second inner isolation pattern DTI_P2 may be connected to the outer isolation patterns DTI_E provided on both sides in the second direction (Y direction) crossing the first direction (X direction). That is, the second inner isolation pattern DTI_P2 may be provided between inner walls of the outer isolation pattern DTI_E extending in the first direction (X direction). The second inner isolation patterns DTI_P2 may be spaced apart from each other at the central portion CP of the pixel group PXGa. The second inner isolation pattern DTI_P2 may protrude in the second direction (Y direction) toward the central portion CP of the pixel group PXGa. For example, each of two second inner isolation patterns DTI_P2 protruding in the second direction (Y direction) may be spaced apart from the central portion CP of the pixel group PXGa. The second inner isolation pattern DTI_P2 may be symmetric with respect to the central portion CP of the pixel group PXGa.

For example, a third distance D3 at which the second inner isolation patterns DTI_P2 are spaced apart from each other in the second direction (Y direction) may be 0.5 times or less of a fourth distance D4 between the inner walls of the outer isolation pattern DTI_E extending in the first direction (X direction). For example, the third distance D3 at which the second inner isolation patterns DTI_P2 are spaced apart from each other in the second direction (Y direction) may be 0.05 to 0.4 times the fourth distance D4 between the inner walls of the outer isolation pattern DTI_E extending in the first direction (X direction). That is, a sum of lengths of the second inner isolation patterns DTI_P2 extending in the second direction (Y direction) may be greater than the third distance D3 at which the second inner isolation patterns DTI_P2 are spaced apart from each other in the second direction (Y direction).

Since the first inner isolation pattern DTI_P1 and the second inner isolation pattern DTI_P2 are respectively spaced apart from each other at the central portion CP of the pixel group PXGa, photocharges between adjacent pixels PX may move through the spaced portion. Accordingly, the sensing sensitivity of the pixel group PXGa may be increased.

Since the inner isolation pattern DTI_P is provided between the first to fourth photodiodes PD11 to PD14, incident light incident to each of the first to fourth photodiodes PD11 to PD14 and photocharges generated by the incident light may be prevented from being incident to adjacent pixels PX. That is, the inner isolation pattern DTI_P may prevent a crosstalk phenomenon between the first to fourth photodiodes PD11 to PD14. In addition, the outer isolation pattern DTI_E may prevent a cross torque phenomenon between respective pixel groups PXGa and adjacent pixel groups PXGa.

According to an embodiment, the auxiliary isolation pattern 300 may be provided between a plurality of inner isolation patterns DTI_P spaced apart from each other. For example, as shown in FIG. 5, the auxiliary isolation pattern 300 may be provided between a plurality of first inner isolation patterns DTI_P1 spaced apart from each other. In addition, the auxiliary isolation pattern 300 may be provided between a plurality of second inner isolation patterns DTI_P2 spaced apart from each other. In other words, the auxiliary isolation pattern 300 may be provided between the first inner isolation patterns DTI_P1 extending in the first direction (X direction) and between the second inner isolation patterns DTI_P2 extending in the second direction (Y direction).

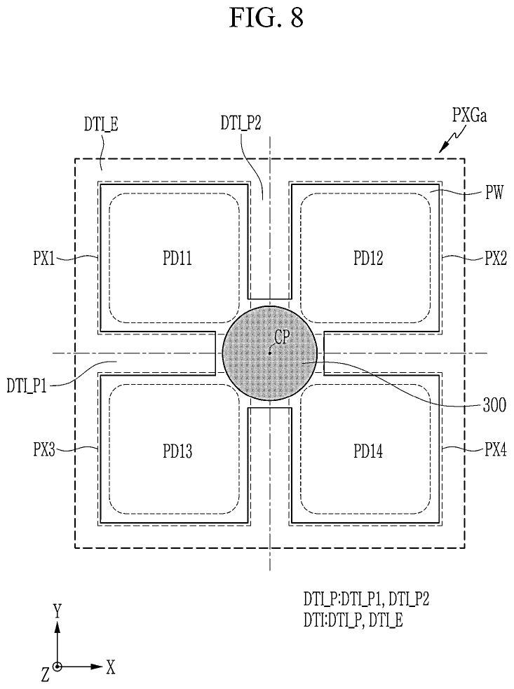

According to an embodiment, the auxiliary isolation pattern 300 may be provided at the central portion CP of the pixel group PXGa. The auxiliary isolation pattern 300 may be surrounded by the inner isolation pattern DTI_P. However, the disclosure is not limited thereto, and as such, according to another embodiment, the auxiliary isolation pattern 300 may be provided between the inner isolation pattern DTI_P and the outer isolation pattern DTI_E that are spaced apart from each other. This will be described later with reference to FIG. 8.

The auxiliary isolation pattern 300 may contact the inner isolation pattern DTI_P. For example, as shown in FIG. 5, the auxiliary isolation pattern 300 may contact one side of each of the two first inner isolation patterns DTI_P1 (left side and right side patterns DTI_P1) and the two second inner isolation patterns DTI_P2 (upper side and lower side patterns DTI_P2). However, the number of pixel isolation patterns DTI contacting the auxiliary isolation pattern 300 is not limited thereto. As such, according to another embodiment, the auxiliary isolation pattern 300 may not contact all of the two first inner isolation patterns DTI_P1 and the two second inner isolation patterns DTI_P2. For example, the auxiliary isolation pattern 300 may not contact some of the two first inner isolation patterns DTI_P1 and the two second inner isolation patterns DTI_P2. In another embodiment, the auxiliary isolation pattern 300 may not directly contact any of the two first inner isolation patterns DTI_P1 and the two second inner isolation patterns DTI_P2. In addition, the auxiliary isolation pattern 300 may be provided to be spaced apart from the inner isolation pattern DTI_P. This will be described later with reference to FIG. 8. The auxiliary isolation pattern 300 may not contact the first to fourth photodiodes PD11 to PD14.

According to an embodiment, as the auxiliary isolation pattern 300 is provided between the inner isolation patterns DTI_P spaced apart from each other and the auxiliary isolation pattern 300 contacts the inner isolation pattern DTI_P, a width of the auxiliary isolation pattern 300 may be substantially the same as the distance between the inner isolation patterns DTI_P spaced apart from each other.

For example, the width of the auxiliary isolation pattern 300 in the first direction (X direction) may be may be 0.5 times or less of the second distance D2 between the inner walls of the outer isolation pattern DTI_E extending in the second direction (Y direction). For example, the width of the auxiliary isolation pattern 300 in the first direction (X direction) may be 0.05 to 0.4 times the second distance D2 between the inner walls of the second outer isolation pattern DTI_E extending in the second direction (Y direction). In addition, the width of the auxiliary isolation pattern 300 in the second direction (Y direction) may be may be 0.5 times or less of the fourth distance D4 between the inner walls of the outer isolation pattern DTI_E extending in the first direction (X direction). For example, the width of the auxiliary isolation pattern 300 in the second direction (Y direction) may be 0.05 to 0.4 times the fourth distance D2 between the inner walls of the second outer isolation pattern DTI_E extending in the first direction (X direction).

However, the disclosure is not limited thereto, and as such, according to another embodiment, the auxiliary isolation pattern 300 may be provided to be spaced apart from the inner isolation pattern DTI_P. In this case, the width of the auxiliary isolation pattern 300 may be smaller than the distance between the inner isolation patterns DTI_P spaced apart from each other. In a plan view, the auxiliary isolation pattern 300 may have a circular shape. For example, in a plan view, the auxiliary isolation pattern 300 may have a circular shape having the central portion CP of the pixel group PXGa as a center. However, the disclosure is not limited thereto, and as such, according to another embodiment, the auxiliary isolation pattern 300 may have a shape such as an elliptical shape or a polygonal shape. Even in this case, the auxiliary isolation pattern 300 may not contact the first to fourth photodiodes PD11 to PD14.

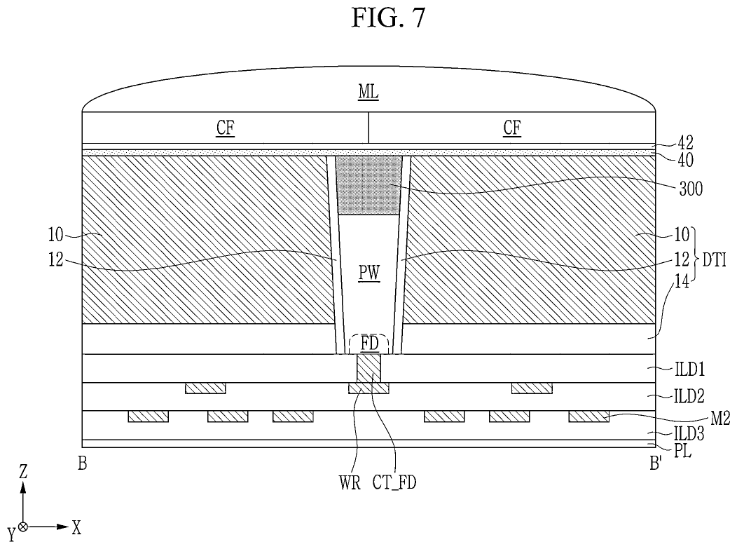

Hereinafter, an image sensor according to an embodiment will be described with further reference to FIG. 6 and FIG. 7.

FIG. 6 illustrates a cross-sectional view taken along line A-A′ of FIG. 4. FIG. 7 illustrates a cross-sectional view taken along line B-B′ of FIG. 4.

Referring further to FIGS. 6 and 7, the image sensor 100 according to the embodiment may include a substrate 2, a pixel isolation pattern DTI, an element isolation pattern STI, a transmission gate TG, a floating diffusion area FD, photodiodes PD, an auxiliary isolation pattern 300, color filters CF, and microlenses ML.

The substrate 2 may be, for example, a bulk silicon or a silicon-on-insulator (SOI). The substrate 2 may be a silicon substrate, or may include other materials, for example, a silicon germanium, an indium antimonide, a lead tellurium compound, an indium arsenic, an indium phosphide, a gallium arsenic, or a gallium antimonide. According to another embodiment, the substrate 2 may have an epitaxial layer formed on a base substrate. The substrate 2 may be doped with impurities. For example, the substrate 2 may be doped with P-type impurities.

The substrate 2 may include a first surface 2a and a second surface 2b facing each other. The first surface 2a of the substrate 2 may be a light receiving surface through which light is incident. In addition, the second surface 2b may be a front surface of substrate 2, and the first surface 2a may be a rear surface of substrate 2. The second surface 2b may be a surface opposite to the first surface 2a.

The pixel isolation pattern DTI may be provided between adjacent pixel groups PXGa and between adjacent pixels PX. The pixel isolation pattern DTI may isolate the photodiodes PD included in the pixel group PXGa. For example, the pixel isolation pattern DTI may electrically and optically isolate the first to fourth photodiodes PD11 to PD14 included in the pixel group PXGa.

The pixel isolation pattern DTI may pass through the substrate 2. The pixel isolation pattern DTI may extend from the second surface 2b of the substrate 2 in a third direction (Z direction). For example, the pixel isolation pattern DTI may connect the second surface 2b and the first surface 2a of the substrate 2. However, the disclosure is not limited thereto, and as such, according to another embodiment, the pixel isolation pattern DTI may be spaced apart from the first surface 2a of the substrate 2.

The pixel isolation pattern DTI includes an outer isolation pattern DTI_E for isolating each pixel group PXG and an inner isolation pattern DTI_P for isolating the pixels PX included in each pixel group PXG from each other.

The outer isolation pattern DTI_E may surround each pixel group PXGa.

The inner isolation pattern DTI_P may be provided between adjacent pixels PX. For example, the inner isolation pattern DTI_P may be provided between the first to fourth pixels PX1 to PX4, respectively. Each of the first to fourth pixels PX1 to PX4 may be isolated by the inner isolation pattern DTI_P.

The inner isolation pattern DTI_P may extend in the first direction (X direction) and the second direction (Y direction) in a plan view, and may be provided between the photodiodes PD adjacent to each other. The inner isolation pattern DTI_P may electrically and/or optically isolate adjacent photodiodes PD from each other. The inner isolation patterns DTI_P may be spaced apart from each other at a central portion CP within each pixel group PXGa.

According to an embodiment, the side surface of the pixel isolation pattern DTI may have an inclined shape with respect to the first surface 2a of the substrate 2. For example, the inclined surface may have a tapered shape. However, the disclosure is not limited thereto, and as, according to another embodiment, the side surface of the pixel isolation pattern DTI may include a plane perpendicular to the first surface 2a of the substrate 2. That is, the width of the pixel isolation pattern DTI may be constant. According to another embodiment, the side surface of the pixel isolation pattern DTI may have an inclined shape with respect to the first surface 2a of the substrate 2, the inclined surface may have a reverse tapered shape. In other words, the width of the pixel isolation pattern DTI may decrease from the upper surface of the pixel isolation pattern DTI to the lower surface of the pixel isolation pattern DTI.

The pixel isolation pattern DTI according to the embodiment may include an isolation conductive pattern 10, a capping insulation pattern 14, and an isolation insulation pattern 12.

The isolation conductive pattern 10 may be provided in the substrate 2. For example, the isolation conductive pattern 10 may be provided inside the substrate 2. For example, the isolation conductive pattern 10 may extend from the second surface 2b of the substrate 2 towards the first surface 2a of the substrate 2. That is, the isolation conductive pattern 10 may extend from the second surface 2b of the substrate 2 in the third direction (Z direction). The isolation conductive pattern 10 may be spaced apart from the first surface 2a of the substrate 2. The thickness of the isolation conductive pattern 10 in the third direction (Z direction) may be greater than the thickness of the auxiliary isolation pattern 300 in the third direction (Z direction). The isolation conductive pattern 10 may include a conductive material having a refractive index different from that of the substrate 2. The isolation conductive pattern 10 may include, for example, polysilicon or metal doped with impurities.

The capping insulation pattern 14 may be provided under the isolation conductive pattern 10. The capping insulation pattern 14 may be provided inside the substrate 2. For example, the capping insulation pattern 14 may extend from the first surface 2a of the substrate 2. The capping insulation pattern 14 may include, for example, at least one of a silicon oxide, a silicon oxynitride, and a silicon nitride.

The isolation insulation pattern 12 may be provided between the isolation conductive pattern 10 and the substrate 2. The isolation insulation pattern 12 may cover side surfaces of the isolation conductive pattern 10 and the capping insulation pattern 14. The isolation insulation pattern 12 may include an insulation material having a refractive index different from that of the substrate 2. For example, the isolation insulation pattern 12 may include a silicon oxide.

According to an embodiment, each of the side surface of the isolation conductive pattern 10, the side surface of the capping insulation pattern 14, and the side surface of the isolation insulation pattern 12 has a inclined shape with respect to the first surface 2a of the substrate 2, and in this case, the inclined surface is shown as having a tapered shape. However, the disclosure is not limited thereto, and as such, according to another embodiment, at least one of the side surface of the isolation conductive pattern 10, the side surface of the capping insulation pattern 14, and the side surface of the isolation insulation pattern 12 may have a shape perpendicular to the first surface 2a of the substrate 2 or a reverse tapered shape.

The element isolation pattern STI may extend from the first surface 2a of the substrate 2 in the third direction (Z direction). The element isolation pattern STI may be provided inside the substrate 2. For example, the element isolation pattern STI may extend from the first surface 2a of the substrate 2 towards the second surface 2b of the substrate. The element isolation pattern STI may be spaced apart from the second surface 2b of the substrate 2. The element isolation pattern STI may be provided on the side surface of the capping insulation pattern 14. The element isolation pattern STI may be formed on the first surface 2a by a shallow trench isolation (STI) method. The element isolation pattern STI may be made of have a single layer structure or a multi-layer structure of at least one of a silicon oxide layer, a silicon nitride layer, and a silicon oxynitride layer.

The transmission gate TG may be provided in the substrate 2. For example, the transmission gate TG may be embedded in the substrate 2. The transmission gate TG may be a vertical type. For example, the transmission gate TG may include a first transmission gate portion 21 provided on the first surface 2a of the substrate 2 and a second transmission gate portion 22 protruding into the substrate 2. According to another embodiment, the transmission gate TG may be a planar type including only the first transmission gate portion 21 without the second transmission gate portion 22. A gate insulation film Gox may be interposed between the transmission gate TG and the substrate 2. The gate insulation film Gox may include a single film or multi-film of at least one of a silicon oxide film, a metal oxide silicon nitride film, and a silicon oxide nitride film.

The floating diffusion area FD may be provided within the substrate 2. The floating diffusion area FD may have a predetermined depth from the first surface 2a of the substrate 2. The floating diffusion area FD may be doped with impurities doped in the substrate 2. For example, the floating diffusion area FD may be doped with N-type impurities (for example, phosphorus or arsenic).

The photodiodes PD for receiving light may be provided in the substrate 2. Light incident from the outside may be converted into electrical signals by the photodiodes PD.

The photodiode PD may be provided to correspond to each pixel PX. For example, the second photodiode PD12 may be provided to correspond to the second pixel PX2, and the third photodiode PD13 may be provided to correspond to the third pixel PX3. The photodiodes PD may be doped with impurities different from those of the substrate 2. For example, the photodiodes PD may be doped with N-type impurities.

The side surfaces of the photodiodes PD may include reverse tapered inclined surfaces inclined with respect to the second surface 2b of the substrate 2. For example, the side surfaces of the photodiodes PD may have a reverse trapezoidal shape in a cross-sectional view. Accordingly, the width of the photodiodes PD may decrease from the upper surface to the lower surface. The width of the upper surface of the photodiodes PD may be greater than the width of the lower surface of the auxiliary isolation pattern 300. In addition, the distance between adjacent photodiodes PD may increase from the upper surface to the lower surface.

The image sensor 100 according to the embodiment may further include a well area PW provided between the photodiodes PD and the first surface 2a and between the adjacent photodiodes PD.

The well area PW may be doped with, for example, P-type impurities doped in the substrate 2. A concentration of impurities doped in the well area PW may be equal to or greater than that of impurities doped in the substrate 2. The photodiodes PD may be doped with impurities. For example, the photodiodes PD may be doped with N-type impurities (for example, phosphorus or arsenic). An area of the photodiodes PD in which the N-type impurities are doped may form a PN junction with the surrounding substrate 2 and/or the P-type impurity area of the well area PW to form the photodiodes PD, and when light is incident, electron-hole pairs may be generated by the PN junction.

The auxiliary isolation pattern 300 may be provided between the photodiodes PD. For example, the auxiliary isolation pattern 300 may be provided between adjacent third photodiode PD13 and second photodiode PD12. The auxiliary isolation pattern 300 may not contact the photodiode PD.

The auxiliary isolation pattern 300 may be provided in the second surface 2b of the substrate 2. For example, the auxiliary isolation pattern 300 may be embedded in the second surface 2b of the substrate 2. The auxiliary isolation pattern 300 may be provided inside the substrate 2 from the second surface 2b of the substrate 2. That is, the auxiliary isolation pattern 300 may extend from the second surface 2b of the substrate 2 in the third direction (Z direction). In addition, the auxiliary isolation pattern 300 may be provided to be spaced apart from the first surface 2a of the substrate 2. The upper surface of the auxiliary isolation pattern 300 may be provided at the same level as the second surface 2b of the substrate 2. In another example case, the upper surface of the auxiliary isolation pattern 300 may substantially the same level as the second surface 2b of the substrate 2. Accordingly, the first thickness T1 of the auxiliary isolation pattern 300 in the third direction (Z direction) may be smaller than the thickness of the substrate 2 in the third direction (Z direction).

The upper surface of the auxiliary isolation pattern 300 may be provided at the same level as the upper surface of the pixel isolation pattern DTI. In another example case, the upper surface of the auxiliary isolation pattern 300 may be provided at substantially the same level as the upper surface of the pixel isolation pattern DTI. The first thickness T1 of the auxiliary isolation pattern 300 in the third direction (Z direction) may be smaller than the thickness of the pixel isolation pattern DTI in the third direction (Z direction).

The upper surface of the auxiliary isolation pattern 300 may be provided at a higher level than the upper surface of the photodiodes PD. That is, the upper surface of the auxiliary isolation pattern 300 may be provided farther from the first surface 2a of the substrate 2 than the upper surface of the photodiodes PD. In addition, the lower surface of the auxiliary isolation pattern 300 may be provided at a higher level than the lower surfaces of the photodiodes PD. That is, the lower surface of the auxiliary isolation pattern 300 may be provided farther from the first surface 2a of the substrate 2 than the lower surface of the photodiodes PD.

In addition, the first thickness T1 of the auxiliary isolation pattern 300 in the third direction (Z direction) may be smaller than the thicknesses of the photodiodes PD in the third direction (Z direction). For example, the first thickness T1 of the auxiliary isolation pattern 300 in the third direction (Z direction) may be smaller than the second thickness T2 of the third photodiode PD13 in the third direction (Z direction). For example, the ratio of the first thickness T1 of the auxiliary isolation pattern 300 in the third direction (Z direction) to the second thickness T2 of the third photodiode PD13 in the third direction (Z direction) may be 1:10 to 1:2.

According to an embodiment, the auxiliary isolation pattern 300 may overlap the floating diffusion area FD in the third direction (Z direction). In an example, at least a portion of the auxiliary isolation pattern 300 may overlap the floating diffusion area FD in the third direction (Z direction). In an example, the auxiliary isolation pattern 300 may overlap at least a portion of the floating diffusion area FD in the third direction (Z direction). As described above, since the lower surface of the auxiliary isolation pattern 300 is provided at a higher level than the lower surfaces of the photodiodes PD, the auxiliary isolation pattern 300 may be spaced apart from the floating diffusion area FD. Accordingly, the well area PW may be provided between the auxiliary isolation pattern 300 and the floating diffusion area FD.

The side surface of the auxiliary isolation pattern 300 may contact the pixel isolation pattern DTI. For example, as shown in FIG. 7, the side surface of the auxiliary isolation pattern 300 may contact the isolation insulation pattern 12. However, the disclosure is not limited thereto, and as such, according to another embodiment, the side surface of the auxiliary isolation pattern 300 may be spaced apart from the isolation insulation pattern 12.

The side surface of the auxiliary isolation pattern 300 may have a reverse tapered shape inclined with respect to the second surface 2b of the substrate 2. For example, the side surface of the auxiliary isolation pattern 300 may have a reverse trapezoidal shape in a cross sectional view. Accordingly, the width of the auxiliary isolation pattern 300 may decrease from the upper surface to the lower surface. That is, the width of the upper surface of the auxiliary isolation pattern 300 may be greater than the width of the lower surface of the auxiliary isolation pattern 300.

However, the disclosure is not limited thereto, and as such, according to another embodiment, the side surface of the auxiliary isolation pattern 300 may include a vertical surface or a surface perpendicular to the second surface 2b of the substrate 2. In addition, in some embodiments, the side surface of the auxiliary isolation pattern 300 may have a reverse tapered shape inclined with respect to the second surface 2b of the substrate 2. For example, the side surface of the auxiliary isolation pattern 300 may have a trapezoidal shape in a cross sectional view. According to another embodiment, the side surface of the auxiliary isolation pattern 300 may include a curved surface.

According to an embodiment, the process of forming the auxiliary isolation pattern 300 may include forming the pixel isolation pattern DTI on the first surface 2a of the substrate 2 and then forming the auxiliary isolation pattern 300 on the second surface 2b of the substrate 2. Specifically, a pixel isolation pattern trench is formed on the first surface 2a of the substrate 2. Thereafter, the isolation insulation pattern 12, the isolation conductive pattern 10, and the capping insulation pattern 14 may be formed in the pixel isolation pattern trench. Next, an auxiliary isolation pattern trench may be formed on the second surface 2b of the substrate 2. The auxiliary isolation pattern trench may be provided between the isolation patterns DTI that are spaced apart from each other. In this case, a side surface of the auxiliary isolation pattern trench may include a reverse tapered inclined surface inclined with respect to the second surface 2b of the substrate 2, but is not limited thereto. For example, the side surface of the auxiliary isolation pattern trench may include a vertical surface or an inclined taper inclined surface. Subsequently, an insulating material may be filled in the auxiliary isolation pattern trench to form the auxiliary isolation pattern 300.

That is, the auxiliary isolation pattern 300 may be back-side deep trench isolation (BDTI).

In the process of forming the auxiliary isolation pattern 300, an insulating material is formed to cover the auxiliary isolation pattern trench and the second surface 2b of the substrate 2, and then a chemical mechanical polishing (CMP) process is performed, so that the second surface 2b of the substrate 2 may be planarized. However, the disclosure is not limited thereto, and as such, the auxiliary isolation pattern 300 may be formed in another manner or by using another technique.

The auxiliary isolation pattern 300 may include an insulating material. For example, the auxiliary isolation pattern 300 may have a single layer or multilayer structure of at least one of a silicon oxide, a silicon nitride, a silicon oxynitride, and a porous insulation material.

As another example, the auxiliary isolation pattern 300 may be formed of an area doped with impurities. For example, the auxiliary isolation pattern 300 may be doped with P-type impurities. In this case, the auxiliary isolation pattern 300 may refer to an area in which a doping concentration of P-type impurities is 50% or more based on an area in which a doping concentration of P-type impurities is highest.

The image sensor 100 according to the embodiment may further include first to third interlayer insulation films ILD1, ILD2, and ILD3, a passivation film PL, a fixed charge film 40 and an anti-reflection film 42.

The first to third interlayer insulation films ILD1, ILD2, and ILD3 and the passivation film PL may be sequentially stacked on the first surface 2a of the substrate 2. Each of the first to third interlayer insulation films ILD1, ILD2, and ILD3 may have a single film or multi-film structure of, for example, at least one of a silicon oxide, a silicon nitride, a silicon oxynitride, and a porous insulation material. The passivation film PL may include, for example, a silicon nitride.

A connection wire may be provided between the first interlayer insulation film ILD1 and the second interlayer insulation film ILD2. The connection wire may be connected to the floating diffusion area FD by a floating diffusion contact (CT_FD) penetrating the first interlayer insulation film ILD1.

According to an embodiment, first wires may be further provided between the first interlayer insulation film ILD1 and the second interlayer insulation film ILD2.

Some of the first wires may be transmission gate wires. That is, the transmission gate wire may be provided on the same layer as the connection wire WR. The transmission gate wire may be connected to the transmission gate TG.

Some of the first wires may be ground wires. The ground wire may be a wire connected to a ground area to which a ground voltage or a negative bias voltage is applied.

Second wires M2 may be provided between the second interlayer insulation film ILD2 and the third interlayer insulation film ILD3. Some of the first wires may be connected to some of the second wires M2 by vias penetrating the second interlayer insulation film ILD2.

The fixed charge film 40 may be provided on the second surface 2b of the substrate 2. The fixed charge film 40 may contact the second surface 2b. The fixed charge film 40 may be made of a metal oxide or a metal fluoride including at least one of hafnium (Hf), zirconium (Zr), aluminum (Al), tantalum (Ta), titanium (Ti), yttrium, and lanthanoids. Hole accumulation may occur around the fixed charge film 40. Accordingly, occurrence of dark current and white spots may be effectively reduced. The fixed charge film 40 may preferably be at least one of an aluminum oxide film and a hafnium oxide film. The anti-reflection film 42 may be provided on the fixed charge film 40. The anti-reflection film 42 may include, for example, a silicon nitride.

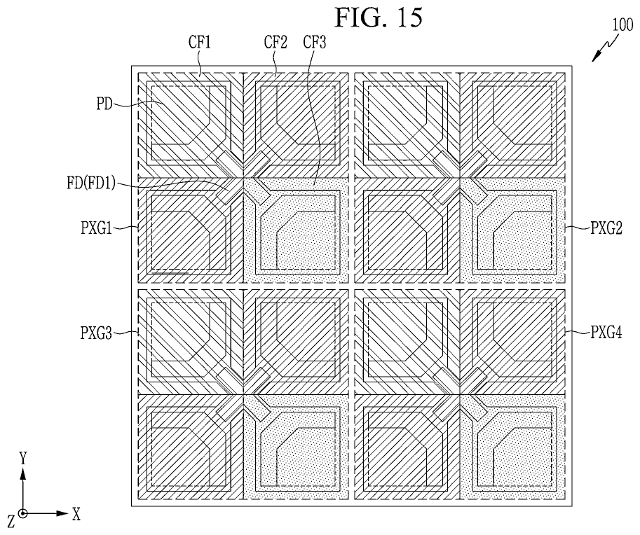

The color filters CF may be provided on the second surface 2b of the substrate 2. For example, the color filters CF may be provided on the anti-reflection film 42. The color filters CF may be provided to respectively correspond to the photodiodes PD. The micro lenses ML condensing light incident from the outside may be provided on each color filter CF. The color filters CF and the micro lenses ML will be described later with reference to FIG. 15 to FIG. 18.

Hereinafter, other embodiments of the image sensor will be described with reference to FIGS. 8 to 14.

FIG. 8 illustrates a schematic top plan view of a pixel group of an image sensor according to an embodiment.

The image sensor according to the embodiment shown in FIG. 8 has considerably the same portions as the image sensor according to the embodiment shown in FIGS. 1 to 7, and as such, a description thereof will be omitted and differences will be mainly described. In addition, the same reference numerals are used for components that are the same as those of the embodiment shown in FIGS. 1 to 7. According to an embodiment, a width of the inner isolation pattern DTI_P is different from that of the embodiment shown in FIGS. 1 to 7, which will be described below.

Referring to FIG. 8, the pixel group PXGa may be applied to the first to fourth pixel groups PXG1 to PXG4 of FIG. 2.

The pixel group PXGa of the image sensor 100 according to some embodiments may include first to fourth pixels PX1 to PX4, first to fourth photodiodes PD11 to PD14, and an auxiliary isolation pattern 300.

The auxiliary isolation pattern 300 may contact the inner isolation pattern DTI_P. For example, as shown in FIG. 5, the auxiliary isolation pattern 300 may contact one side of each of two first inner isolation patterns DTI_P1 and two second inner isolation patterns DTI_P2.

According to an embodiment illustrated in FIG. 8, the auxiliary isolation pattern 300 may be provided to be spaced apart from the inner isolation pattern DTI_P. For example, the auxiliary isolation pattern 300 may be spaced apart from each of the first inner isolation patterns DTI_P1 extending in the first direction (X direction), in the first direction (X direction). In addition, the auxiliary isolation pattern 300 may be provided to be spaced apart from each of the second inner isolation patterns DTI_P2 extending in the second direction (Y direction). The well area PW may be provided between the auxiliary isolation pattern 300 and the first inner isolation pattern DTI_P1 and between the auxiliary isolation pattern 300 and the second inner isolation pattern DTI_P2.

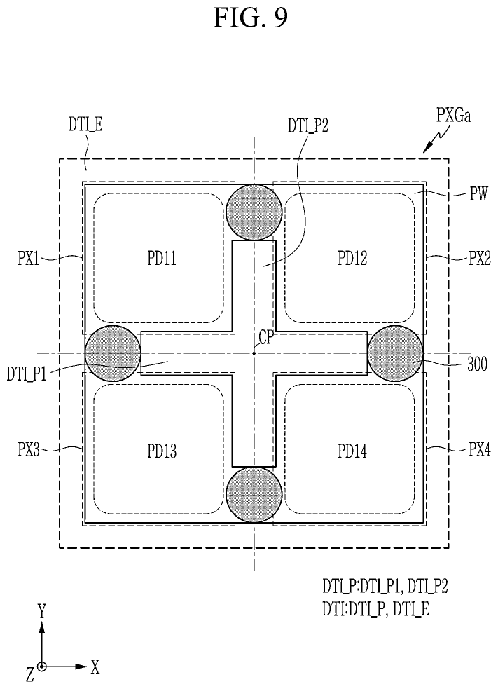

FIG. 9 illustrates a schematic top plan view of a pixel group of an image sensor according to an embodiment.

The image sensor according to the embodiment shown in FIG. 9 has considerably the same portions as the image sensor according to the embodiment shown in FIGS. 1 to 7, and as such, a description thereof will be omitted and differences will be mainly described. In addition, the same reference numerals are used for components that are the same as those of the embodiment shown in FIGS. 1 to 7. In the embodiment illustrated in FIG. 9, the shape of the inner isolation pattern DTI_P and the shape of the auxiliary isolation pattern 300 are different from those of the embodiment shown in FIGS. 1 to 7, which will be described below.

Referring to FIG. 9, the pixel group PXGa may be applied to the first to fourth pixel groups PXG1 to PXG4 of the image sensor 100 of FIG. 2.

The pixel group PXGa of the image sensor 100 according to some embodiments may include first to fourth pixels PX1 to PX4, first to fourth photodiodes PD11 to PD14, and an auxiliary isolation pattern 300.

The inner isolation pattern DTI_P of the embodiment shown in FIGS. 1 to 7 may be connected to the outer isolation pattern DTI_E. Specifically, the first inner isolation pattern DTI_P1 may be connected to the outer isolation pattern DTI_E provided on both sides in the first direction (X direction). In addition, the second inner isolation pattern DTI_P2 may be connected to the outer isolation patterns DTI_E provided on both sides in the second direction (Y direction) crossing the first direction (X direction).

The inner isolation patterns DTI_P may be spaced apart from each other at the central portion CP of the pixel group PXGa. Specifically, the first inner isolation patterns DTI_P1 may be spaced apart from each other along the first direction (X direction) at the central portion CP of the pixel group PXGa. In addition, the second inner isolation patterns DTI_P2 may be spaced apart from each other along the second direction (Y direction) at the central portion CP of the pixel group PXGa.

In addition, the auxiliary isolation pattern 300 may be provided between a plurality of inner isolation patterns DTI_P spaced apart from each other. Specifically, the auxiliary isolation pattern 300 may be provided between the first inner isolation patterns DTI_P1 extending in the first direction (X direction) and between the second inner isolation patterns DTI_P2 extending in the second direction (Y direction). The auxiliary isolation pattern 300 may be provided at the central portion CP of the pixel group PXGa. Accordingly, the auxiliary isolation pattern 300 may be surrounded by the inner isolation pattern DTI_P.

Referring to FIG. 9, the first inner isolation pattern DTI_P1 may extend along the first direction (X direction) from the central portion CP of the pixel group PXGa to both sides thereof. The first inner isolation pattern DTI_P1 may be spaced apart from the outer isolation pattern DTI_E. For example, each of both sides of the first inner isolation pattern DTI_P1 may be spaced apart from the outer isolation pattern DTI_E in the first direction (X direction). The first inner isolation pattern DTI_P1 may be symmetric with respect to the central portion CP of the pixel group PXGa.

In addition, the second inner isolation pattern DTI_P2 may extend from the central portion CP of the pixel group PXGa to both sides thereof along the second direction (Y direction). The second inner isolation pattern DTI_P2 may be spaced apart from the outer isolation pattern DTI_E. For example, each of both sides of the second inner isolation pattern DTI_P2 may be spaced apart from the outer isolation pattern DTI_E in the second direction (Y direction). The second inner isolation pattern DTI_P2 may be symmetric with respect to the central portion CP of the pixel group PXGa. The first inner isolation pattern DTI_P1 and the second inner isolation pattern DTI_P2 may cross each other. For example, the first inner isolation pattern DTI_P1 and the second inner isolation pattern DTI_P2 may cross each other to form a cross shape. The inner isolation pattern DTI_P may be surrounded by the outer isolation pattern DTI_E.

In some embodiments, the auxiliary isolation pattern 300 may be provided between the outer isolation pattern DTI_E and the inner isolation pattern DTI_P that are spaced apart from each other. The auxiliary isolation pattern 300 may be provided between each end portion of the inner isolation pattern DTI_P and the outer isolation pattern DTI_E. Specifically, the auxiliary isolation pattern 300 may be provided between the end portion of the first inner isolation pattern DTI_P1 and the outer isolation pattern DTI_E and between the end portion of the second inner isolation pattern DTI_P2 and the outer isolation pattern DTI_E. A detailed description of the remaining shapes of the auxiliary isolation pattern 300 is the same as the embodiment of FIGS. 1 to 7, so it will be omitted.

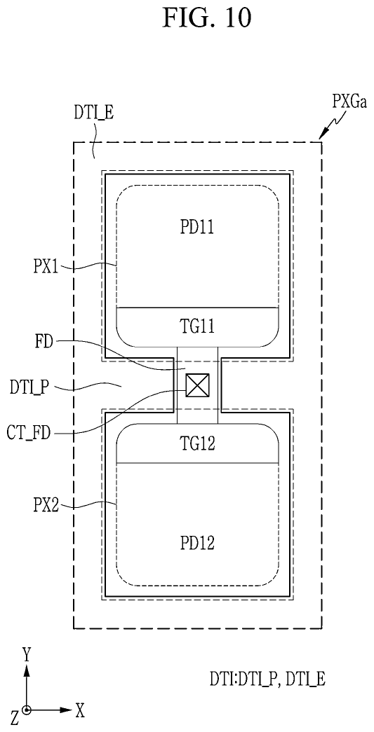

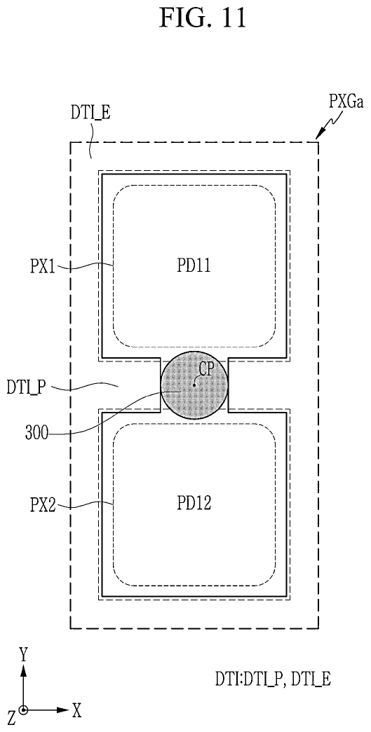

FIGS. 10 and 11 illustrate schematic top plan views of pixel groups of image sensors according to some embodiments.

FIG. 10 illustrates the pixel isolation pattern DTI, the first and second photodiodes PD11 and PD12, the transmission gates TG11 to TG12, and the floating diffusion area FD, and FIG. 11 illustrates the pixel isolation pattern DTI, the first and second photodiodes PD11 to PD12, and the auxiliary isolation pattern 300.

The image sensor according to the embodiment shown in FIGS. 10 and 11 has considerably the same portions as the image sensor according to the embodiment shown in FIGS. 1 to 7, so a description thereof will be omitted and differences will be mainly described. In addition, the same reference numerals are used for components that are the same as those of the embodiment shown in FIGS. 1 to 7. In the embodiment illustrated in FIGS. 10 and 11, the number of the pixels PX included in the pixel group PXGa is different from that of the embodiment shown in FIGS. 1 to 7, which will be described below.

Referring to FIGS. 10 and 11, the pixel group PXGa may be applied to the first to fourth pixel groups PXG1 to PXG4 of the image sensor 100 of FIG. 2.

The pixel group PXGa of the image sensor 100 according to some embodiments may include the first and second pixels PX1 and PX2, the first and second photodiodes PD12, and the auxiliary isolation pattern 300.

The pixel group PXGa of the embodiment shown in FIGS. 1 to 7 may include four pixels arranged along a plurality of columns and a plurality of rows. For example, the pixel group PXGa may include the first to fourth pixels PX11 to PX14. The floating diffusion area FD may be connected to each of the first to fourth pixels PX11 to PX14.

In addition, the inner isolation pattern DTI_P may include the first inner isolation pattern DTI_P1 extending in the first direction (X direction) and the second inner isolation pattern DTI_P2 extending in the second direction (Y direction).

According to an embodiment illustrated in FIGS. 10 and 11, the pixel group PXGa may include two pixels arranged along a plurality of rows. For example, the pixel group PXGa may include the first and second pixels PX1 and PX2 provided along the second direction (Y direction). However, the disclosure is not limited thereto, and as such, according to another embodiment, he pixel group PXGa may include two pixels provided along a plurality of columns.

Each of the first and second pixels PX1 and PX2 of the pixel group PXGa may include one photodiode and one transmission gate. For example, the first pixel PX1 may include the first photodiode PD11 and the first transmission gate TG11. The second pixel PX2 may include the second photodiode PD12 and the second transmission gate TG12. In addition, the pixel group PXGa may include one floating diffusion area FD. The floating diffusion area FD may be connected to each of the first and second pixels PX1 and PX2.

In some embodiments, the outer isolation pattern DTI_E may surround each pixel group PXGa. That is, the outer isolation pattern DTI_E may surround the first and second photodiodes PD11 and PD12.

In some embodiments, the inner isolation pattern DTI_P may extend in the first direction (X direction). The inner isolation pattern DTI_P may be connected to the outer isolation pattern DTI_E provided on both sides in the first direction (X direction). The inner isolation patterns DTI_P may be spaced apart from each other at the central portion CP of the pixel group PXGa. The inner isolation pattern DTI_P may protrude in the first direction (X direction) toward the central portion CP of the pixel group PXGa. For example, each of two inner isolation patterns DTI_P protruding in the first direction (X direction) may be spaced apart from the central portion CP of the pixel group PXGa. The inner isolation pattern DTI_P may be symmetric with respect to the central portion CP of the pixel group PXGa.

The auxiliary isolation pattern 300 may be provided between a plurality of inner isolation patterns DTI_P spaced apart from each other. In other words, the auxiliary isolation pattern 300 may be provided between inner isolation patterns DTI_P extending in the first direction (X direction).

According to an embodiment, the auxiliary isolation pattern 300 may be provided at the central portion CP of the pixel group PXGa. The auxiliary isolation pattern 300 may be surrounded by the inner isolation pattern DTI_P. The remaining description of the auxiliary isolation pattern 300 is substantially the same as the embodiment of FIGS. 1 to 7, and thus will be omitted.

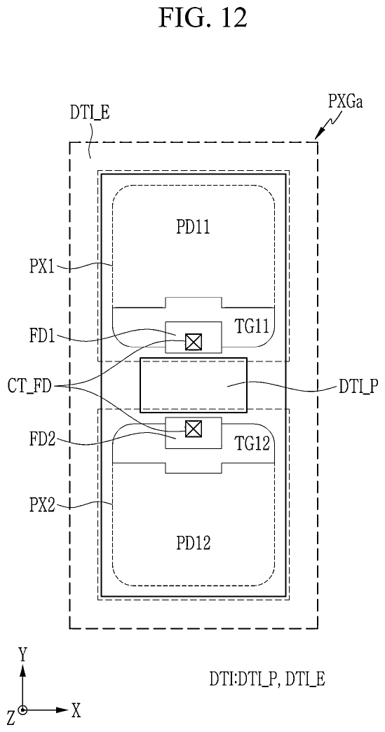

FIGS. 12 to 14 illustrate schematic top plan views of pixel groups of image sensors according to some embodiments.

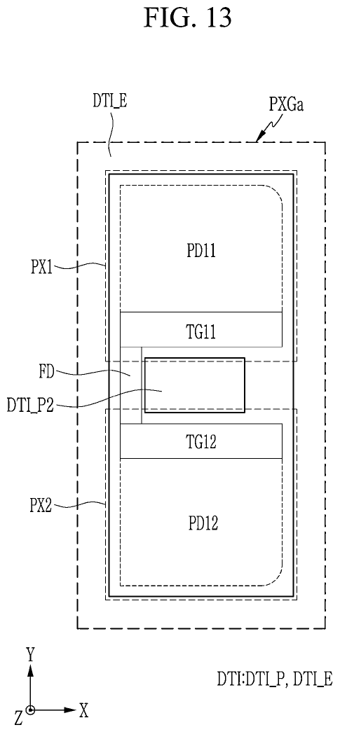

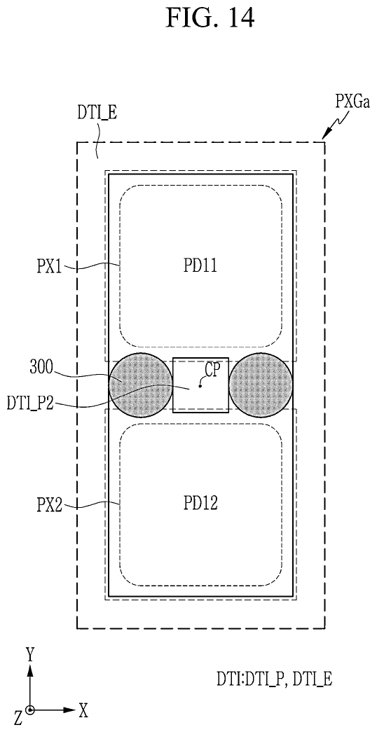

FIGS. 12 and 13 illustrate the pixel isolation pattern DTI, the first and second photodiodes PD11 and PD12, the transmission gates TG11 to TG12, and the floating diffusion area FD, and FIG. 14 illustrates the pixel isolation pattern DTI, the first and second photodiodes PD11 and PD12, and the auxiliary isolation pattern 300.

The image sensor illustrated according to the embodiment in FIGS. 12 to 14 has considerably the same portions as the image sensor shown according to the embodiment in FIGS. 10 and 11, and as such, a description thereof will be omitted and differences will be mainly described. In addition, the same reference numerals are used for components that are the same as those of the embodiment shown in FIGS. 10 and 11. According to an embodiment illustrated in FIGS. 12 to 14, the shape of the inner isolation pattern DTI_P and the shape of the auxiliary isolation pattern 300 are different from those of the embodiment shown in FIGS. 10 and 11, which will be described below.

Referring to FIGS. 12 to 14, the pixel group PXGa may be applied to the first to fourth pixel groups PXG1 to PXG4 of the image sensor 100 of FIG. 2.

The pixel group PXGa of the image sensor 100 according to some embodiments may include the first and second pixels PX1 and PX2, the first and second photodiodes PD12, and the auxiliary isolation pattern 300.

The inner isolation pattern DTI_P of the embodiment shown in FIGS. 10 and 11 may be connected to the outer isolation pattern DTI_E provided on both sides in the first direction (X direction). The inner isolation patterns DTI_P may be spaced apart from each other at the central portion CP of the pixel group PXGa.

In addition, the auxiliary isolation pattern 300 may be provided between a plurality of inner isolation patterns DTI_P spaced apart from each other. The auxiliary isolation pattern 300 may be provided at the central portion CP of the pixel group PXGa.

Referring to FIGS. 12 to 14, the pixel group PXGa may include two floating diffusion areas FD. For example, as shown in FIG. 12, the first pixel PX1 may include the first floating diffusion area FD1, and the second pixel PX2 may include the second floating diffusion area FD2. In this case, the first and second floating diffusion areas FD1 and FD2 may be electrically connected through a connection wire. The connection wire may be connected to the first and second floating diffusion areas FD1 and FD2 by the floating diffusion contact CT_FD. According to another embodiment, as shown in FIG. 13, the pixel group PXGa may include one floating diffusion area FD. In this case, the floating diffusion area FD may be connected to each of the first and second pixels PX1 and PX2.

In some embodiments, the inner isolation pattern DTI_P may extend from the central portion CP of the pixel group PXGa to both sides thereof along the first direction (X direction). The inner isolation pattern DTI_P may be spaced apart from the outer isolation pattern DTI_E. For example, each of both sides of the inner isolation pattern DTI_P may be spaced apart from the outer isolation pattern DTI_E in the first direction (X direction). The inner isolation pattern DTI_P may be symmetric with respect to the central portion CP of the pixel group PXGa.

In some embodiments, the auxiliary isolation pattern 300 may be provided between the outer isolation pattern DTI_E and the inner isolation pattern DTI_P that are spaced apart from each other. The auxiliary isolation pattern 300 may be provided between each end portion of the inner isolation pattern DTI_P and the outer isolation pattern DTI_E. Specifically, the auxiliary isolation pattern 300 may be provided between the end portion of the first inner isolation pattern DTI_P1 and the outer isolation pattern DTI_E and between the end portion of the second inner isolation pattern DTI_P2 and the outer isolation pattern DTI_E. A detailed description of the remaining shapes of the auxiliary isolation pattern 300 is the same as the embodiment of FIGS. 10 and 11, and thus will be omitted.

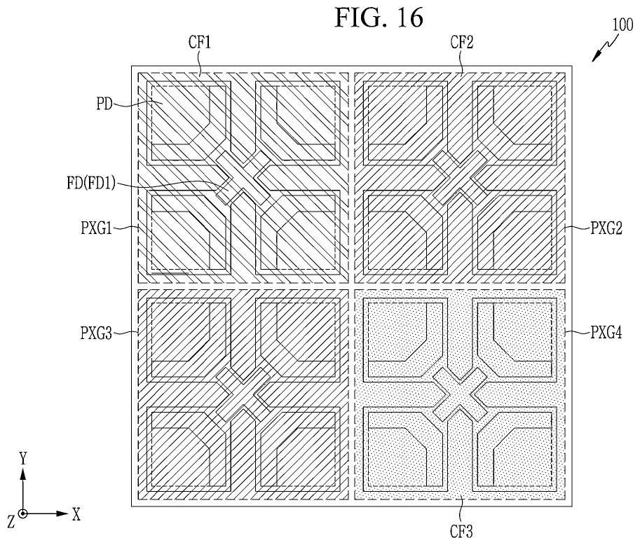

Hereinafter, a color filter of an image sensor according to an embodiment will be described with reference to FIGS. 15 to 16.

FIGS. 15 to 16 illustrate schematic top plan views of a color filter of an image sensor according to an embodiment.

Referring to FIG. 15, as described above, the color filters CF may be provided corresponding to respective photodiodes PD.

The color filters CF may include a first color filter CF1, a second color filter CF2, and a third color filter CF3. For example, the first color filter CF1 may be a red color filter, the second color filter CF2 may be a green color filter, and the third color filter CF3 may be a blue color filter.

According to an embodiment, the color filters CF may have a Bayer pattern in a plan view. For example, the color filters CFs may have a pattern in which the number of the second color filters CF2 is about twice as many as the number of the first color filters CF1 or the third color filters CF3. That is, in the color filters CF arranged in a 2×2 shape in a plan view, the Bayer pattern may include two second color filters CF2 provided diagonally to each other, and the first color filter CF1 and the third color filter CF3 provided diagonally to each other. Each of the first color filter CF1 and the third color filter CF3 may be provided between adjacent second color filters CF2. The color filters CF of the Bayer pattern may be repeatedly arranged along the first direction (X direction) and the second direction (Y direction).

However, the disclosure is not limited thereto, and as such, according to another embedment, the number of the photodiodes PD corresponding to one color filter CF may be variously changed. For example, the photodiodes PD of an N×M array may correspond to one color filter CF. Here, N and M may each independently be an integer greater than 1. For example, as shown in FIG. 16, in an example case in which N and M are 2, four photodiodes PD may correspond to one color filter CF.

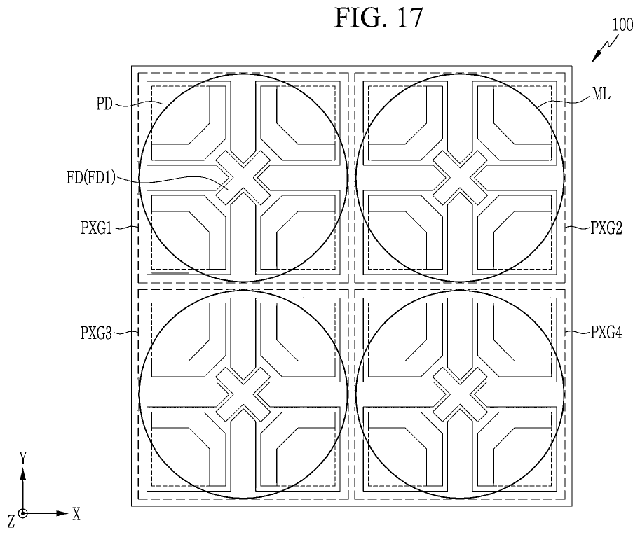

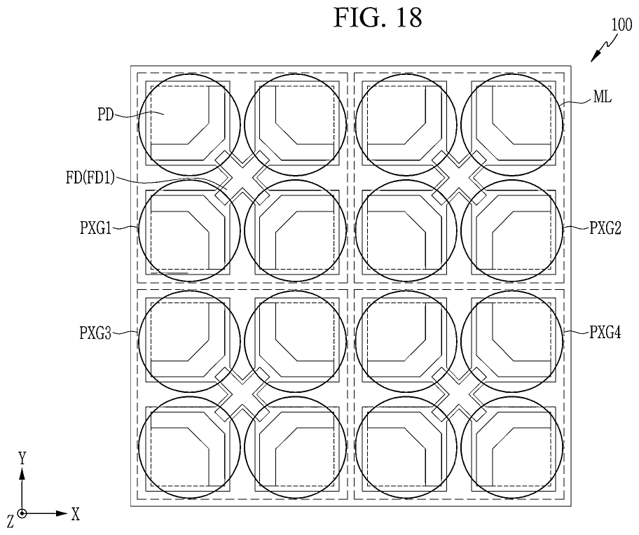

Hereinafter, a micro lens of an image sensor according to an embodiment will be described with reference to FIGS. 17 and 18.

FIGS. 17 and 18 illustrate schematic top plan views of a micro lens of an image sensor according to an embodiment.

Referring to FIG. 17, the micro lenses ML condensing light incident from the outside may be provided on the photodiodes PD. For example, the photodiodes PD of an N×M array may correspond to one micro lens ML. Here, N and M may each independently be an integer greater than 1. For example, as shown in FIG. 17, in an example case in which N and M are 2, four photodiodes PD may correspond to one micro lens ML.

However, the disclosure is not limited thereto, and the number of the photodiodes PD corresponding to one micro lens ML may be variously changed. For example, as shown in FIG. 18, one micro lens ML may be provided on one photodiode PD. That is, a ratio between the number of the photodiodes PD and the number of the micro lenses ML may be 1:1.

According to an embodiment, an upper surface of the micro lens ML may have a curved surface. However, the disclosure is not limited thereto, and in some embodiments, the upper surface of the microlens ML may have a quadrangular shape having rounded corners.

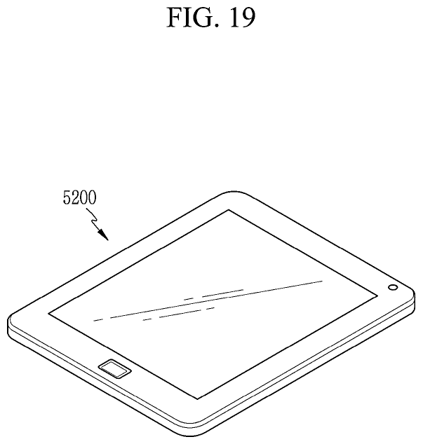

Hereinafter, an application example of the image sensor according to the embodiment will be described with reference to FIGS. 19 to 22.

FIGS. 19 to 22 are drawings illustrating various examples of electronic devices to which image sensors according to example embodiments are applied.

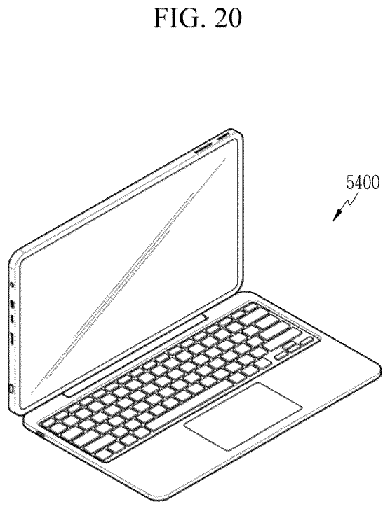

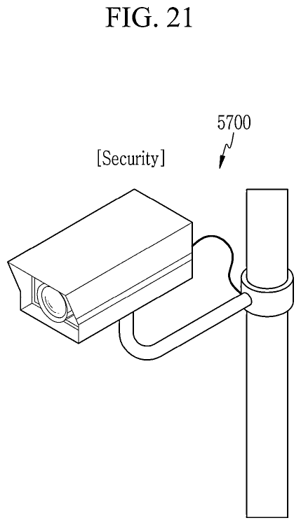

The image sensor 100 according to the embodiments may be applied to a mobile phone or a smart phone, a tablet or a smart tablet 5200 shown in FIG. 19, a laptop computer 5400 shown in FIG. 20, or a security camera 5700 shown in FIG. 21. For example, the smart phone or the smart tablet 5200 may include a plurality of high resolution cameras each equipped with a high resolution image sensor. The high resolution camera may be used to extract depth information from subjects in an image, control out-focusing of the image, or automatically identify subjects in the image. The security camera 5700 may provide ultra-high resolution images and may recognize objects or people in the images even in a dark environment by using high sensitivity.

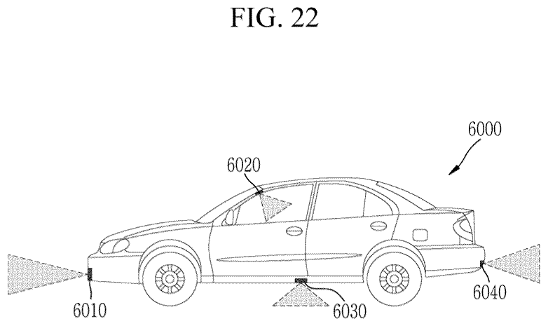

In addition, the image sensor 100 may be applied to a vehicle 6000 as shown in FIG. 22. The vehicle 6000 may include a plurality of vehicle cameras 6010, 6020, 6030, and 6040 provided at various positions, and each of the vehicle cameras 6010, 6020, 6030, and 6040 may include the image sensor according to the embodiment. The vehicle 6000 may use the plurality of vehicle cameras 6010, 6020, 6030, and 6040 to provide a driver with various information about the inside or surroundings of the vehicle 6000, and may automatically recognize objects or people in an image to provide information necessary for autonomous driving.

While the embodiment of the disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. An image sensor comprising:
a substrate comprising a first surface and a second surface;
a plurality of pixel groups, each of the plurality of pixel groups comprising a plurality of photodiodes provided in the substrate;
a pixel isolation pattern provided between the plurality of photodiodes in the substrate;
an auxiliary isolation pattern provided in the substrate, the auxiliary isolation pattern extending from the second surface of the substrate into the substrate; and
a micro lens provided on the second surface of the substrate,
wherein the pixel isolation pattern comprises:
an outer isolation pattern provided between the plurality of pixel groups, and an inner isolation pattern comprising:
a first inner isolation pattern provided between two first adjacent photodiodes, among the plurality of photodiodes, and
a second inner isolation pattern provided between two second adjacent photodiodes, among the plurality of photodiodes, and
wherein the auxiliary isolation pattern is provided between the outer isolation pattern and one of the first and the second inner isolation patterns that are spaced apart from each other or between the first inner isolation pattern and the second inner isolation pattern that are spaced apart from each other.

2. The image sensor of claim 1, wherein
the first inner isolation pattern and the second inner isolation pattern are spaced apart from each other at a central portion within the plurality of pixel groups, and
the auxiliary isolation pattern is provided at the central portion within the plurality of pixel groups.

3. The image sensor of claim 2, wherein
each of the plurality of pixel groups comprises four photodiodes,
the four photodiodes are provided along a first direction and a second direction crossing the first direction,
the first inner isolation pattern and the second inner isolation pattern extend along the first direction or the second direction, and
the outer isolation pattern surrounds the four photodiodes and is connected to the first inner isolation pattern and the second inner isolation pattern.

4. The image sensor of claim 2, wherein
each of the plurality of pixel groups comprises two photodiodes,
the two photodiodes are provided along a first direction,
the first inner isolation pattern and the second inner isolation pattern extend along a second direction crossing the first direction, and
the outer isolation pattern surrounds the two photodiodes and is connected to the first inner isolation pattern and the second inner isolation pattern.

5. The image sensor of claim 1, wherein
the auxiliary isolation pattern is in contact with or spaced apart from the pixel isolation pattern.

6. The image sensor of claim 1, wherein
the outer isolation pattern, the first inner isolation pattern and the second inner isolation pattern are spaced apart from each other at an edge portion of the plurality of pixel groups, and
the auxiliary isolation pattern is provided at an edge portion of the plurality of pixel groups.

7. The image sensor of claim 6, wherein
the inner isolation pattern has a cross shape and is surrounded by the outer isolation pattern, and
the auxiliary isolation pattern is provided between each end portion of the inner isolation pattern and the outer isolation pattern.

8. The image sensor of claim 1, wherein
the pixel isolation pattern is configured to penetrate the substrate in a vertical direction.

9. The image sensor of claim 1, further comprising:
a transmission transistor connected to each of the plurality of photodiodes; and
a floating diffusion area connected to at least two photodiodes through the transmission transistor,
wherein the auxiliary isolation pattern overlaps the floating diffusion area in a vertical direction.

10. The image sensor of claim 1, wherein
a thickness of the auxiliary isolation pattern in a vertical direction is smaller than a thickness of the substrate in the vertical direction.

11. The image sensor of claim 10, wherein
the thickness of the auxiliary isolation pattern in the vertical direction is smaller than a thickness of the plurality of photodiodes in the vertical direction.

12. An image sensor comprising:
a substrate comprising a first surface and a second surface;
a plurality of pixel groups, each of the plurality of pixel groups comprising a plurality of photodiodes provided in the substrate;
a pixel isolation pattern provided between the plurality of photodiodes in the substrate;
an element isolation pattern provided in the substrate, the element isolation pattern extending inside the substrate from the first surface of the substrate; and
an auxiliary isolation pattern provided in the substrate, the auxiliary isolation pattern extending inside the substrate from the second surface of the substrate,
wherein the pixel isolation pattern comprises:
an outer isolation pattern provided between the plurality of pixel groups, and
an inner isolation pattern comprising:
a first inner isolation pattern provided between two first adjacent photodiodes, among the plurality of photodiodes, and
a second inner isolation pattern provided between two second adjacent photodiodes, among the plurality of photodiodes, and
wherein the auxiliary isolation pattern is provided between the outer isolation pattern and one of the first and the second inner isolation patterns that are spaced apart from each other or between the first inner isolation pattern and the second inner isolation pattern that are spaced apart from each other.

13. The image sensor of claim 12, wherein
a thickness of the auxiliary isolation pattern in a vertical direction is smaller than a thickness of the plurality of photodiodes in the vertical direction.

14. The image sensor of claim 13, wherein
a ratio of the thickness of the auxiliary isolation pattern in the vertical direction to the thickness of the plurality of photodiodes in the vertical direction is 1:10 to 1:2.

15. The image sensor of claim 12, wherein
a thickness of the auxiliary isolation pattern in a vertical direction is smaller than a thickness of the pixel isolation pattern in the vertical direction.

16. The image sensor of claim 12, further comprising
a color filter provided on the second surface of the substrate; and
a micro lens provided on the color filter.

17. An image sensor comprising:
a substrate comprising a first surface and a second surface;
a plurality of pixel groups, each of the plurality of pixel groups comprising a plurality of photodiodes provided in the substrate;
a plurality of pixel isolation patterns, each provided between adjacent photodiodes among the plurality of photodiodes in the substrate; and
an auxiliary isolation pattern provided in the substrate, the auxiliary isolation pattern extending inside the substrate from the first surface of the substrate and provided between two pixel isolation patterns, among the plurality of pixel isolation patterns spaced apart from each other,
wherein each of the plurality of pixel isolation patterns comprises:
an isolation conductive pattern extending inwardly from the second surface of the substrate,
a capping insulation pattern extending inwardly from the first surface of the substrate, and
an isolation insulation pattern provided on side surfaces of the isolation conductive pattern and the capping insulation pattern.

18. The image sensor of claim 17, wherein
a thickness of the auxiliary isolation pattern in a vertical direction is smaller than a thickness of the plurality of photodiodes in the vertical direction.

19. The image sensor of claim 17, wherein
the plurality of pixel isolation patterns are spaced apart from each other at a central portion within the plurality of pixel groups, and
the auxiliary isolation pattern is provided at the central portion within the plurality of pixel groups and the auxiliary isolation pattern is in contact with or spaced apart from the pixel isolation pattern.

20. The image sensor of claim 17, further comprising:
a transmission transistor connected to each of the plurality of photodiodes; and
a floating diffusion area connected to at least two photodiodes through the transmission transistor,
wherein the auxiliary isolation pattern overlaps the floating diffusion area in a vertical direction.
